(19) United States
(12) Patent Application Publication
(10) Pub. No.: US 2025/0093115 A1
(43) Pub. Date: Mar. 20, 2025

(54) COOLING SYSTEM ASSEMBLY

(71) Applicant: Purple Cloud Development Pte. Ltd., Singapore (SG)

(72) Inventor: Chia-chin Chan, Singapore (SG)

(21) Appl. No.: 18/822,215

(22) Filed: Sep. 1, 2024

(30) Foreign Application Priority Data
Sep. 20, 2023 (TW) 112210156

(51) Int. Cl. F28F 9/02; F17D 1/08; F24F 7/06; F28F 3/02

(52) U.S. Cl. CPC F28F 9/0275; F17D 1/08; F24F 7/06; F28F 3/02; F28F 2009/0292; F28F 2009/0295

(57) ABSTRACT

A cooling system assembly may include a water block unit and liquid cooling unit. The water block unit is configured for phase-change of a first cooling fluid and the liquid cooling unit is configured to be flow through by a second cooling fluid. The water block unit includes a first thermal transfer surface and second thermal transfer surface. The first thermal transfer surface is configured to couple to a packaged integrated circuit. The liquid cooling unit includes a liquid plate heat exchanger comprising a liquid cooling water block coupled to the second thermal transfer surface. The first thermal transfer surface is thermally coupled to the packaged integrated circuit, whereby the water block unit transports heat away from the packaged integrated circuit. The liquid cooling water block is thermally coupled to the second thermal transfer surface, whereby the liquid cooling unit transports heat away from the water block unit.

### RELATED APPLICATIONS

This US application claims the benefit of priority to Taiwan application no. 112210156, filed on Sep. 20, 2023, of which is incorporated herein by reference in its entirety.

### TECHNICAL FIELD

The present disclosure relates to heat-transfer components and assemblies, and more particularly, but not limited to, water block unit assemblies.

### BACKGROUND OF THE INVENTION

With increasing processing speed and performance of electronic devices, the amount of heat generated during operation of an electronic device has increased. The heat generation increases the temperature of the electronic device and, if the heat cannot be dissipated effectively, the reliability and performance of the electronic device is reduced. To prevent overheating of an electronic device, cooling systems such as air-cooling systems and liquid cooling systems are used to efficiently dissipate the heat generated by the electronic device and, thereby ensure the standard operation of the electronic device.

In the case of air-cooling systems for packaged integrated circuits, heat is dissipated from an upper surface of a packaged integrated circuit via upper surface adherence of a heatsink or water block unit to the packaged integrated circuit. The heatsink or water block unit is commonly mounted to the packaged integrated circuits via attachment members such as screws and push pins. Thermal pads (also called thermally conductive pad or thermal interface pad) and thermal paste (also called thermal compound, thermal grease, thermal interface material (TIM), heat sink compound, heat sink paste or CPU grease) may be used to enhance adherence and aid in heat conduction. Notwithstanding however, given same design parameters, increasing thermal conductivity of air-cooling systems continue to be challenging.

### SUMMARY OF THE INVENTION

The present disclosure provides a cooling system assembly with higher thermal conductivity.

In some aspects, the techniques described herein relate to a cooling system assembly, including a water block unit and a liquid cooling unit. The water block unit is configured for phase-change of a first cooling fluid. The water block unit includes a water block comprising a first thermal transfer surface and a second thermal transfer surface. The second thermal transfer surface is opposite the first thermal transfer surface. The first thermal transfer surface is configured to couple to at least one packaged integrated circuit. The liquid cooling unit is configured to be flow through by a second cooling fluid. The liquid cooling unit includes a liquid plate heat exchanger comprising a liquid cooling water block. The liquid cooling water block is coupled to the second thermal transfer surface. The first thermal transfer surface is thermally coupled to the at least one packaged integrated circuit, whereby the water block unit transports heat away from the at least one packaged integrated circuit. The liquid cooling water block is thermally coupled to the second thermal transfer surface, whereby the liquid cooling unit transports heat away from the water block unit.

In some aspects, the techniques described herein relate to a cooling system assembly, wherein the water block unit further includes a fin stack and a plurality of heat pipes. Each plurality of heat pipes is respectively coupled to the water block on one end and each plurality of heat pipes is respectively coupled to the fin stack on an other end. The other end is opposite the one end. In some aspects, the techniques described herein relate to a cooling system assembly, wherein the plurality of heat pipes includes five plurality of heat pipes. In some aspects, the techniques described herein relate to a cooling system assembly, wherein the fin stack is disposed on one side of the water block unit.

In some aspects, the techniques described herein relate to a cooling system assembly, wherein the water block unit further includes a fan unit coupled to the fin stack, the fan unit configured to force air across the fin stack. In some aspects, the techniques described herein relate to a cooling system assembly, wherein the fan unit includes more than one rotatable fan.

In some aspects, the techniques described herein relate to a cooling system assembly, further including a circuit board assembly including a circuit board. The water block further includes a plurality of attachment hubs protruding from the water block, and the liquid plate heat exchanger includes a plurality of counterbores. Each plurality of counterbores aligns with and receives each plurality of attachment hubs. The liquid cooling unit is configured to couple to the water block unit via a plurality of attachment members. Each plurality of attachment members fasten the liquid cooling unit to the water block unit via the plurality of counterbores and the plurality of attachment hubs. The liquid cooling unit and the water block unit are coupled to the circuit board.

In some aspects, the techniques described herein relate to a cooling system assembly, wherein the circuit board further includes a socket, a plurality of electronic components, and a plurality of leads. The at least one packaged integrated circuit is electrically coupled to the circuit board via the socket. The plurality of electronic components is electrically coupled to the circuit board via the plurality of leads.

In some aspects, the techniques described herein relate to a cooling system assembly, wherein the fin stack includes an elongated fin stack. The elongated fin stack is disposed on the plurality of electronic components. The elongated fin stack is configured to thermally couple to the plurality of electronic components.

In some aspects, the techniques described herein relate to a cooling system assembly, wherein the plurality of electronic components includes stacked inductor and transistor electronic components. In some aspects, the techniques described herein relate to a cooling system assembly, wherein the at least one packaged integrated circuit includes a graphic processing unit.

In some aspects, the techniques described herein relate to a cooling system assembly, wherein the liquid cooling unit further includes a liquid row heat sink, an inlet manifold, an outlet manifold, an inlet tubing, and an outlet tubing. The liquid plate heat exchanger is in fluid communication with the inlet manifold via the inlet tubing and the liquid plate heat exchanger is in fluid communication with the outlet manifold via the outlet tubing. The liquid row heat sink is configured to lower a flowthrough temperature of ambient airflow flowing through the liquid row heat sink via the second cooling fluid flowing through the liquid row heat sink from the inlet manifold to the outlet manifold.

In some aspects, the techniques described herein relate to a cooling system assembly, wherein the liquid cooling unit further includes a pump unit. The pump unit is disposed within the liquid plate heat exchanger or coupled to the outlet tubing between the liquid plate heat exchanger and the outlet manifold. In some aspects, the techniques described herein relate to a cooling system assembly, wherein the liquid row heat sink is a water-cooled heat sink row.

In some aspects, the techniques described herein relate to a cooling system assembly, wherein the liquid cooling unit further includes a liquid cooling fan unit coupled to the liquid row heat sink. The liquid cooling fan unit is configured to force air across the liquid row heat sink. In some aspects, the techniques described herein relate to a cooling system assembly, wherein the liquid cooling fan unit includes more than one rotatable fan.

In some aspects, the techniques described herein relate to a cooling system assembly, wherein the water block unit further includes a first fin stack, a second fin stack, and a plurality of heat pipes. Each plurality of heat pipes is respectively coupled to the first fin stack on one end and the second fin stack on an other end. The other end is opposite the one end and each plurality of heat pipes is respectively coupled to the water block between the first fin stack and the second fin stack.

In some aspects, the techniques described herein relate to a cooling system assembly, wherein the water block unit further includes a first fan unit coupled to the first fin stack and a second fan unit coupled to the second fin stack. The first fan unit and the second fan unit are respectfully configured to force air across the first fin stack and the second fin stack.

In some aspects, the techniques described herein relate to a cooling system assembly, wherein the plurality of heat pipes includes five plurality of heat pipes.

In some aspects, the techniques described herein relate to a cooling system assembly, wherein the first fin stack is disposed on one side of the water block unit and the second fin stack is disposed on an other side of the water block unit. The other side is opposite the one side.

### BRIEF DESCRIPTION OF DRAWINGS

Unless specified otherwise, the accompanying drawings illustrate aspects of the innovative subject matter described herein. Referring to the drawings, wherein like reference numerals indicate similar parts throughout the several views, several examples of water block units and liquid cooling units incorporating aspects of the presently disclosed principles are illustrated by way of example, and not by way of limitation.

FIG. 1A illustrates a perspective view of a cooling system assembly, in accordance with various embodiments of the present disclosure.

FIG. 1B illustrates an exploded view of the cooling system assembly of FIG. 1A, in accordance with various embodiments of the present disclosure.

FIG. 2 illustrates a perspective view of an alternative cooling system assembly, in accordance with various embodiments of the present disclosure.

FIG. 3A illustrates a perspective view of another alternative cooling system assembly, in accordance with various embodiments of the present disclosure.

FIG. 3B illustrates an exploded view of the cooling system assembly of FIG. 3A, in accordance with various embodiments of the present disclosure.

### DETAILED DESCRIPTION

The following describes various principles related to components and assemblies for electronic devices cooling by way of reference to specific examples of cooling system assemblies, including specific arrangements and examples of water block units and liquid cooling units embodying innovative concepts. More particularly, but not exclusively, such innovative principles are described in relation to selected examples of thermal transfer surfaces of water blocks and liquid plate heat exchangers coupled to the thermal transfer surfaces of water blocks, and well-known functions or constructions are not described in detail for purposes of succinctness and clarity. Nonetheless, one or more of the disclosed principles can be incorporated in various other embodiments of thermal transfer surfaces of water blocks and liquid plate heat exchangers coupled to the thermal transfer surfaces of water blocks to achieve any of a variety of desired outcomes, characteristics, and/or performance criteria.

Thus, thermal transfer surfaces of water blocks and liquid plate heat exchangers coupled to the thermal transfer surfaces of water blocks having attributes that are different from those specific examples discussed herein can embody one or more of the innovative principles, and can be used in applications not described herein in detail. Accordingly, embodiments of thermal transfer surfaces of water blocks and liquid plate heat exchangers coupled to the thermal transfer surfaces of water blocks not described herein in detail also fall within the scope of this disclosure, as will be appreciated by those of ordinary skill in the relevant art following a review of this disclosure.

Example embodiments as disclosed herein are directed to cooling system assemblies that can be used in cooling systems to dissipate high heat loads. The cooling system may be configured on a chassis, within a chassis, or as part of an electronics system that includes heat producing electronic components to be cooled. The cooling system includes at least one cooling system assembly. The cooling system assembly may be coupled to the chassis via a fastener (e.g., bolts, screws, etc.), transporting heat away from heat producing electronic components to be cooled and/or to an outside of the chassis or electronics system. The cooling system may further comprise one or more liquid-based cooling loops.

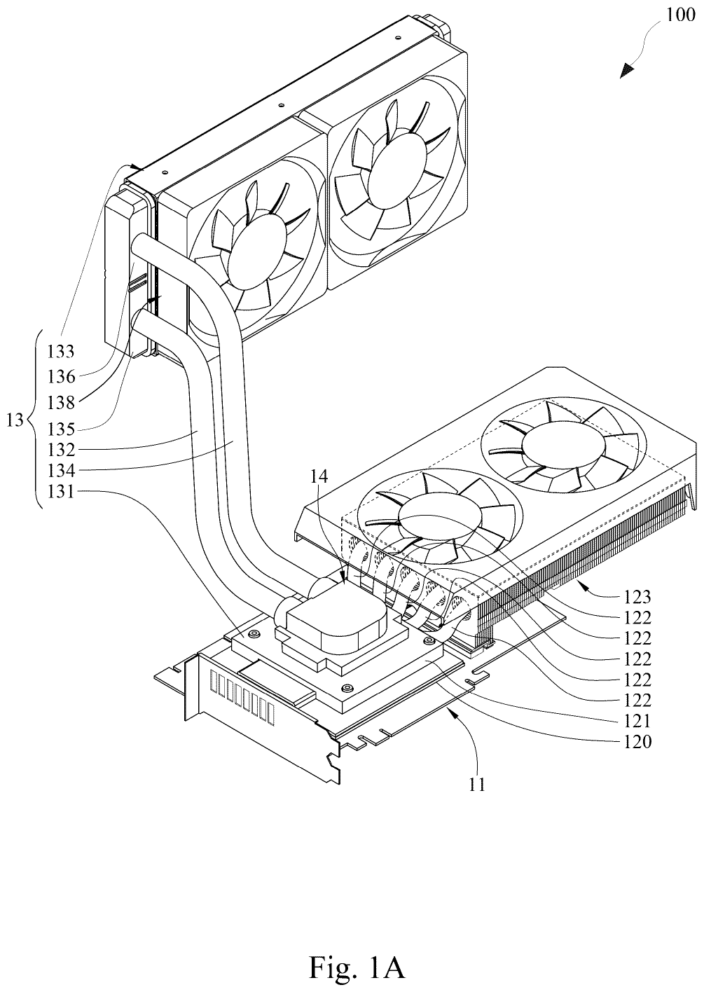

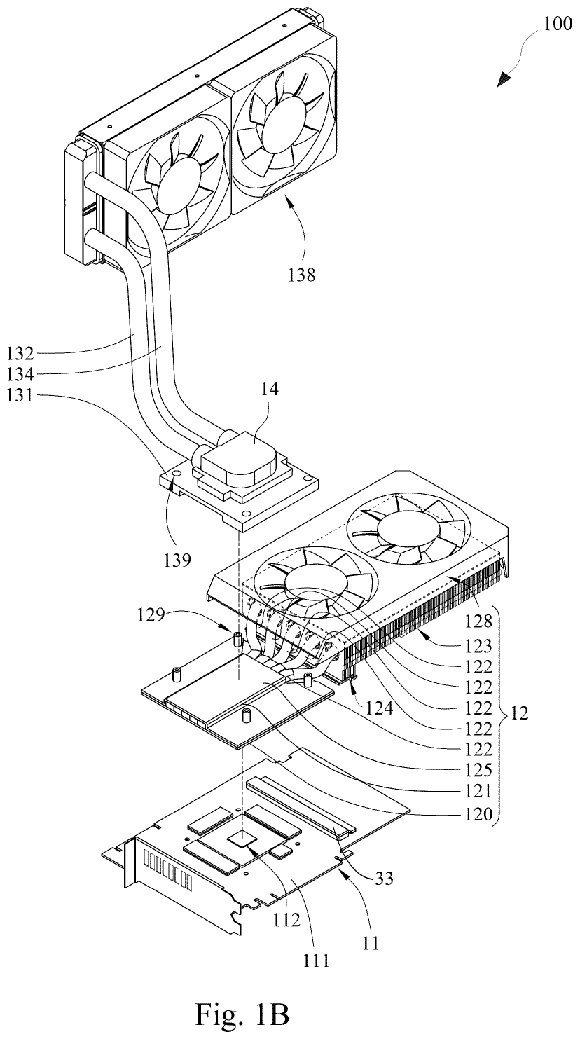

FIGS. 1A and 1B illustrate a cooling system assembly 100, in accordance with various embodiments of the present disclosure. The cooling system assembly 100 includes a water block unit 12 and a liquid cooling unit 13. The water block unit 12 is configured for phase-change of a first cooling fluid. The water block unit 12 includes a water block 121 having a first thermal transfer surface 120 and a second thermal transfer surface 125. The second thermal transfer surface 125 is opposite the first thermal transfer surface 120. The first thermal transfer surface 120 is configured to couple to at least one packaged integrated circuit. The liquid cooling unit 13 is configured to be flow through by a second cooling fluid. The liquid cooling unit 13 includes a liquid plate heat exchanger 14 having a liquid cooling water block 131. The liquid cooling water block 131 is coupled to the second thermal transfer surface 125. The first thermal transfer surface 120 is thermally coupled to the at least one packaged integrated circuit, whereby the water block unit 12 transports heat away from the at least one packaged integrated circuit. The liquid cooling water block 131 is thermally coupled to the second thermal transfer surface 125, whereby the liquid cooling unit 13 transports heat away from the water block unit 12.

In some embodiments, the water block unit 12 further includes a fin stack 123 and a plurality of heat pipes 122. Each plurality of heat pipes 122 is respectively coupled to the water block 121 on one end and each plurality of heat pipes 122 is respectively coupled to the fin stack 123 on an other end. The other end is opposite the one end. In some embodiments, the plurality of heat pipes 122 includes five plurality of heat pipes 122. In some embodiments, the fin stack 123 is disposed on one side of the water block unit 12.

In some embodiments, the water block unit 12 further includes a fan unit 128 coupled to the fin stack 123, the fan unit 128 configured to force air across the fin stack 123. In some embodiments, the fan unit 128 includes more than one rotatable fan.

In some embodiments, the cooling system assembly 100 further includes a circuit board assembly 11 including a circuit board 111. The water block 121 further includes a plurality of attachment hubs 129 protruding from the water block 121 and the liquid plate heat exchanger 14 includes a plurality of counterbores 139. Each plurality of counterbores 139 aligns with and receives each plurality of attachment hubs 129. The liquid cooling unit 13 is configured to couple to the water block unit 12 via a plurality of attachment members (not shown). Each plurality of attachment members fasten the liquid cooling unit 13 to the water block unit 12 via the plurality of counterbores 139 and the plurality of attachment hubs 129. The liquid cooling unit 13 and the water block unit 12 are coupled to the circuit board 111. In some embodiments, the liquid cooling unit 13 and the water block unit 12 are coupled to the circuit board 111 via fasteners or welds.

In some embodiments, the circuit board 111 further includes a socket 112, a plurality of electronic components 33, and a plurality of leads (not shown). The at least one packaged integrated circuit (not shown) is electrically coupled to the circuit board 111 via the socket 112. The plurality of electronic components 33 is electrically coupled to the circuit board 111 via the plurality of leads.

In some embodiments, the fin stack 123 includes an elongated fin stack 124. The elongated fin stack 124 is disposed on the plurality of electronic components 33. The elongated fin stack 124 is configured to thermally couple to the plurality of electronic components 33.

In some embodiments, the plurality of electronic components 33 includes stacked inductor and transistor electronic components. In some embodiments, the circuit board assembly 11 includes an expansion card (or expansion board or add-on card or hardware component), as an example, a graphics card. In some embodiments, the at least one packaged integrated circuit includes a graphic processing unit.

In some embodiments, the liquid cooling unit 13 further includes a liquid row heat sink 133, an inlet manifold 135, an outlet manifold 136, an outlet tubing 134, and an outlet tubing 134. The liquid plate heat exchanger 14 is in fluid communication with the inlet manifold 135 via the inlet tubing 132 and the liquid plate heat exchanger 14 is in fluid communication with the outlet manifold 136 via the outlet tubing 134. The liquid row heat sink 133 is configured to lower a flowthrough temperature of ambient airflow flowing through the liquid row heat sink 133 via the second cooling fluid flowing through the liquid row heat sink 133 from the inlet manifold 135 to the outlet manifold 136. In some embodiments, the liquid row heat sink 133 is a water-cooled heat sink row.

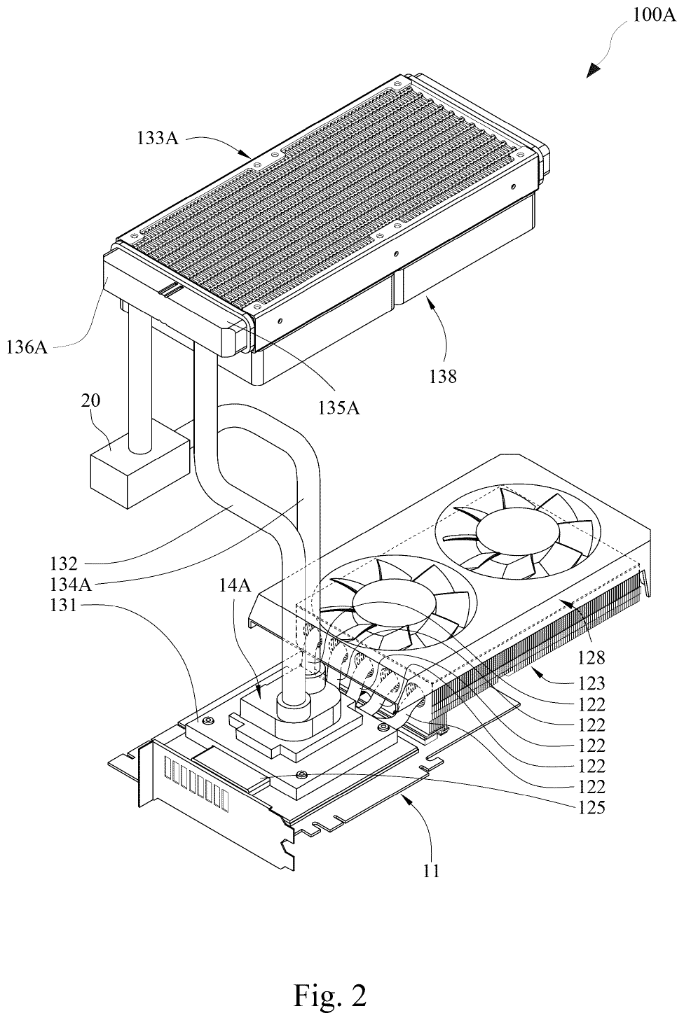

In some embodiments, the liquid cooling unit 13 further includes a pump unit, whereby the pump unit is disposed within the liquid plate heat exchanger 14. FIG. 2 illustrates an alternative cooling system assembly 100A, in accordance with various embodiments of the present disclosure. The alternative cooling system assembly 100A may be similar in some respects to the cooling system assembly 100 of FIGS. 1A and 1B, and therefore may be best understood with reference thereto where like numerals designate like components not described again in detail. In some embodiments, the pump unit 20 of the liquid cooling unit 13A of the alternative cooling system assembly 100A is coupled to the outlet tubing 134A between the liquid plate heat exchanger 14A and the inlet manifold 135A.

In some embodiments, the liquid cooling unit 13 further includes a liquid cooling fan unit 138 coupled to the liquid row heat sink 133. The liquid cooling fan unit 138 is configured to force air across the liquid row heat sink 133. In some embodiments, the liquid cooling fan unit 138 includes more than one rotatable fan.

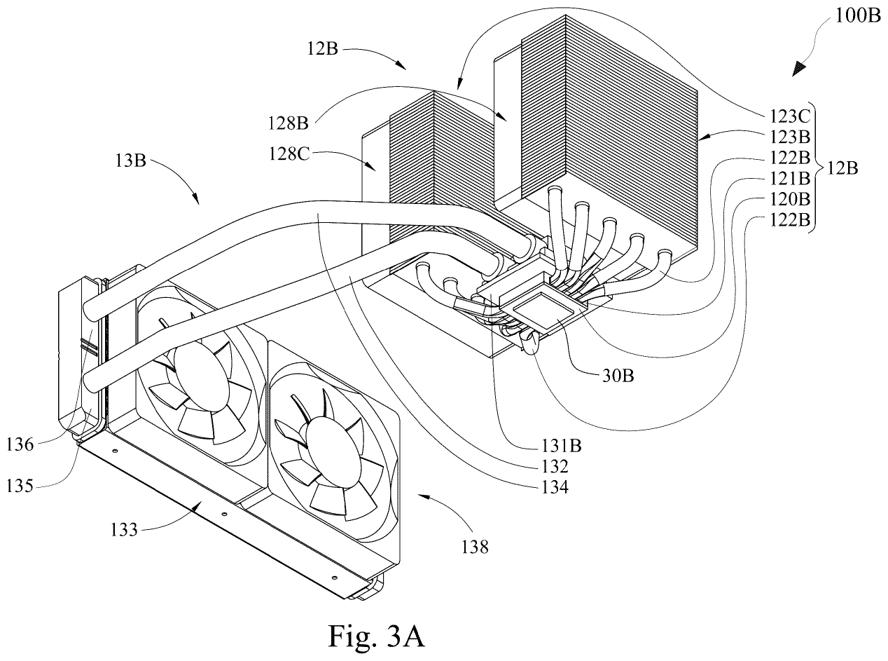

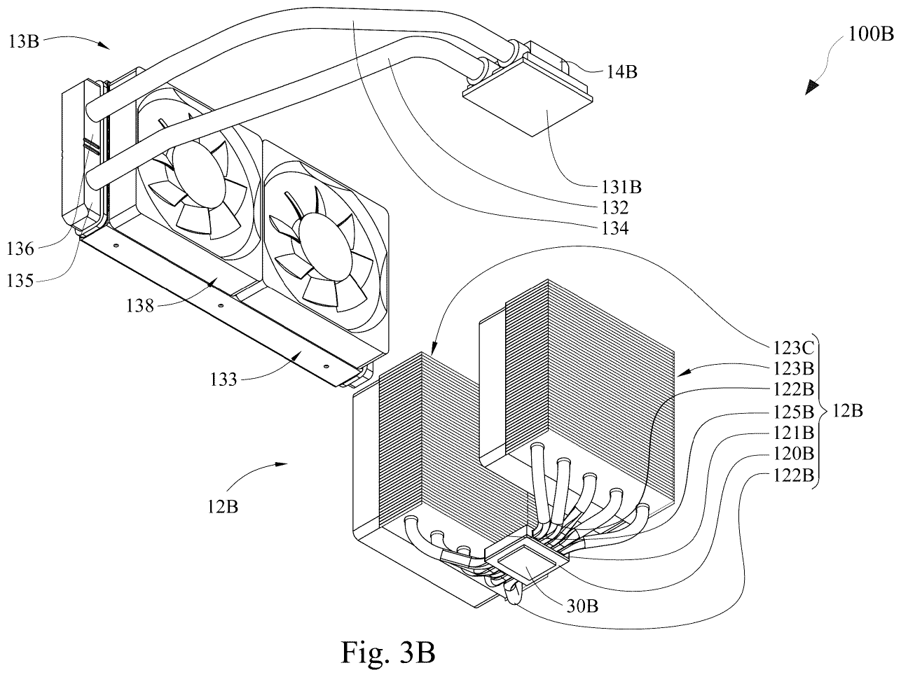

FIGS. 3A and 3B illustrate another alternative cooling system assembly 100B, in accordance with various embodiments of the present disclosure. The another alternative cooling system assembly 100B may be similar in some respects to the cooling system assembly 100 of FIGS. 1A and 1B, and therefore may be best understood with reference thereto where like numerals designate like components not described again in detail. The water block unit 12B of the another alternate cooling system assembly 100B further includes a first fin stack 123B, a second fin stack 123C, and a plurality of heat pipes 122B. Each plurality of heat pipes 122B is respectively coupled to the first fin stack 123B on one end and the second fin stack 123C on an other end. The other end is opposite the one end and each plurality of heat pipes 122B is respectively coupled to the water block 121B between the first fin stack 123B and the second fin stack 123C. In some embodiments, the at least one packaged integrated circuit 30B includes a central processing unit.

In some embodiments, the water block unit 12B further includes a first fan unit 128B coupled to the first fin stack 123B and a second fan unit 128C coupled to the second fin stack 123C. The first fan unit 128B and the second fan unit 128C are respectfully configured to force air across the first fin stack 123B and the second fin stack 123C. In some embodiments, the plurality of heat pipes 122B includes five plurality of heat pipes 122B. In some embodiments, the first fin stack 123B is disposed on one side of the water block unit 12 and the second fin stack 123C is disposed on an other side of the water block unit 12. The other side is opposite the one side. In some embodiments, the water block unit of the cooling system assembly further includes more than two fin stacks.

In some embodiments, the water block 121/121B is made of copper or aluminum. In some embodiments, the relative sizes and dimensions between the liquid plate heat exchanger 14/14A/14B, the liquid cooling water block 131/131B, and the water block 121/121B can be the same or vary. In some embodiments, a vapor chamber may be coupled between the first thermal transfer surface 120 and the at least one packaged integrated circuit. In some embodiments, the liquid cooling water block 131/131B and the water block 121/121B can be integrally formed.

In some embodiments, the pump unit drives the second cooling fluid to transport heat away from the water block unit 12 by driving the second cooling fluid to flow from the liquid cooling water block 131/131B through the liquid plate heat exchanger 14/14A/14B, and then through the inlet tubing 132 to the inlet manifold 135/135A, and then through the liquid row heat sink 133/133A to the outlet manifold 136/136A, and then through the outlet tubing 134/134A back to the liquid plate heat exchanger 14/14A/14B, and then through the liquid cooling water block 131/131B to repeat the flow of the second cooling fluid once again.

In some embodiments, the pump unit drives the second cooling fluid to transport heat away from the water block unit 12 by driving the second cooling fluid to flow from the liquid cooling water block 131/131B through the liquid plate heat exchanger 14/14A/14B, and then through the outlet tubing 134/134A to the outlet manifold 136/136A, and then through the liquid row heat sink 133/133A to the inlet manifold 135/135A, and then through the inlet tubing 132 back to the liquid plate heat exchanger 14/14A/14B, and then through the liquid cooling water block 131/131B to repeat the flow of the second cooling fluid once again.

Given same design parameters, thermal conductivity of the water block units 12/12B of the embodiments is increased. The second thermal transfer surface 125/125B is configured for heat to be transported away from the water block units 12/12B. The fin stack 123 is disposed on one side of the water block unit 12, allowing the liquid cooling water block 131 to be disposed directly on top of the second thermal transfer surface 125, so that the liquid cooling unit 13 can transport heat away from the water block unit 12. Moreover, the liquid cooling water block 131 further includes a cut out in a corresponding shape of the water block 121, whereby the liquid cooling water block 131 not only encompasses over fifty percent of the second thermal transfer surface 125, the liquid cooling water block 131 is also thermally coupled to at least two respective sides of the water block 121, increasing surface area of where heat is transported away from the water block unit 12. Furthermore, the plurality of counterbores 139 and the plurality of attachment hubs 129 allow the liquid cooling unit 13 and the water block unit 12 to be securely coupled to the circuit board 111, assuring efficient thermal transfer between the first thermal transfer surface 120 and the at least one packaged integrated circuit and between the liquid cooling water block 131 and the second thermal transfer surface 125. Additionally, the first fin stack 123B and the second fin stack 123C are disposed on opposite sides of the water block 121B and spaced apart allowing the liquid cooling water block 131B to be disposed directly on top of the second thermal transfer surface 125B, so that the liquid cooling unit 13B can transport heat away from the water block unit 12B. Thus, greater thermal conductivity of the water block units 12/12B is provided, increasing the effectiveness and efficiency of the cooling system assemblies 100/100A/100B.

Therefore, embodiments disclosed herein are well adapted to attain the ends and advantages mentioned as well as those that are inherent therein. The particular embodiments disclosed above are illustrative only, as the embodiments disclosed may be modified and practiced in different but equivalent manners apparent to those of ordinary skill in the relevant art having the benefit of the teachings herein. Furthermore, no limitations are intended to the details of construction or design herein shown, other than as described in the claims below. It is therefore evident that the particular illustrative embodiments disclosed above may be altered, combined, or modified and all such variations are considered within the scope and spirit of the present disclosure. The embodiments illustratively disclosed herein suitably may be practiced in the absence of any element that is not specifically disclosed herein and/or any optional element disclosed herein. While compositions and methods are described in terms of “comprising,” “containing,” or “including” various components or steps, the compositions and methods can also “consist essentially of” or “consist of” the various components and steps. All numbers and ranges disclosed above may vary by some number. Whenever a numerical range with a lower limit and an upper limit is disclosed, any number and any included range falling within the range is specifically disclosed. In particular, every range of values (of the form, “from about a to about b,” or, equivalently, “from approximately a to b,” or, equivalently, “from approximately a-b”) disclosed herein is to be understood to set forth every number and range encompassed within the broader range of values. Also, the terms in the claims have their plain, ordinary meaning unless otherwise explicitly and clearly defined by the patentee. Moreover, the indefinite articles “a” or “an,” as used in the claims, are defined herein to mean one or more than one of the elements that it introduces.

1. A cooling system assembly, comprising:
a water block unit configured for phase-change of a first cooling fluid, including a water block comprising a first thermal transfer surface and a second thermal transfer surface, the second thermal transfer surface opposite the first thermal transfer surface, the first thermal transfer surface configured to couple to at least one packaged integrated circuit; and
a liquid cooling unit configured to be flow through by a second cooling fluid, including a liquid plate heat exchanger comprising a liquid cooling water block, the liquid cooling water block coupled to the second thermal transfer surface;
wherein the first thermal transfer surface is thermally coupled to the at least one packaged integrated circuit, whereby the water block unit transports heat away from the at least one packaged integrated circuit, and
wherein the liquid cooling water block is thermally coupled to the second thermal transfer surface, whereby the liquid cooling unit transports heat away from the water block unit.

2. The cooling system assembly of claim 1, wherein the water block unit further comprises a fin stack and a plurality of heat pipes, each plurality of heat pipes respectively coupled to the water block on one end and each plurality of heat pipes respectively coupled to the fin stack on an other end, the other end opposite the one end.

3. The cooling system assembly of claim 2, wherein the plurality of heat pipes comprises five plurality of heat pipes.

4. The cooling system assembly of claim 2, wherein the fin stack is disposed on one side of the water block unit.

5. The cooling system assembly of claim 2, wherein the water block unit further comprises a fan unit coupled to the fin stack, the fan unit configured to force air across the fin stack.

6. The cooling system assembly of claim 5, wherein the fan unit comprises more than one rotatable fan.

7. The cooling system assembly of claim 2, further comprising a circuit board assembly including a circuit board, and wherein the water block further comprises a plurality of attachment hubs protruding from the water block, and wherein the liquid plate heat exchanger comprises a plurality of counterbores, each plurality of counterbores aligns with and receives each plurality of attachment hubs, the liquid cooling unit configured to couple to the water block unit via a plurality of attachment members, each plurality of attachment members fasten the liquid cooling unit to the water block unit via the plurality of counterbores and the plurality of attachment hubs, the liquid cooling unit and the water block unit are coupled to the circuit board.

8. The cooling system assembly of claim 7, wherein the circuit board further comprises a socket, a plurality of electronic components, and a plurality of leads, the at least one packaged integrated circuit electrically coupled to the circuit board via the socket, the plurality of electronic components electrically coupled to the circuit board via the plurality of leads.

9. The cooling system assembly of claim 8, wherein the fin stack comprises an elongated fin stack, the elongated fin stack disposed on the plurality of electronic components, the elongated fin stack configured to thermally couple to the plurality of electronic components.

10. The cooling system assembly of claim 8, wherein the plurality of electronic components comprises stacked inductor and transistor electronic components.

11. The cooling system assembly of claim 1, wherein the at least one packaged integrated circuit comprises a graphic processing unit.

12. The cooling system assembly of claim 1, wherein the liquid cooling unit further comprises a liquid row heat sink, an inlet manifold, an outlet manifold, an inlet tubing, and an outlet tubing, the liquid plate heat exchanger is in fluid communication with the inlet manifold via the inlet tubing, the liquid plate heat exchanger is in fluid communication with the outlet manifold via the outlet tubing, the liquid row heat sink is configured to lower a flowthrough temperature of ambient airflow flowing through the liquid row heat sink via the second cooling fluid flowing through the liquid row heat sink from the inlet manifold to the outlet manifold.

13. The cooling system assembly of claim 12, wherein the liquid cooling unit further comprises a pump unit, the pump unit disposed within the liquid plate heat exchanger or coupled to the outlet tubing between the liquid plate heat exchanger and the outlet manifold.

14. The cooling system assembly of claim 12, wherein the liquid row heat sink is a water-cooled heat sink row.

15. The cooling system assembly of claim 12, wherein the liquid cooling unit further comprises a liquid cooling fan unit coupled to the liquid row heat sink, the liquid cooling fan unit configured to force air across the liquid row heat sink.

16. The cooling system assembly of claim 15, wherein the liquid cooling fan unit comprises more than one rotatable fan.

17. The cooling system assembly of claim 1, wherein the water block unit further comprises a first fin stack, a second fin stack, and a plurality of heat pipes, each plurality of heat pipes respectively coupled to the first fin stack on one end, each plurality of heat pipes respectively coupled to the second fin stack on an other end, the other end opposite the one end, each plurality of heat pipes respectively coupled to the water block between the first fin stack and the second fin stack.

18. The cooling system assembly of claim 17, wherein the water block unit further comprises a first fan unit coupled to the first fin stack and a second fan unit coupled to the second fin stack, the first fan unit and the second fan unit respectfully configured to force air across the first fin stack and the second fin stack.

19. The cooling system assembly of claim 17, wherein the plurality of heat pipes comprises five plurality of heat pipes.

20. The cooling system assembly of claim 17, wherein the first fin stack is disposed on one side of the water block unit and the second fin stack is disposed on an other side of the water block unit, the other side opposite the one side.
